(19) United States
(12) Patent Application Publication
(10) Pub. No.: US 2023/0212392 A1
(43) Pub. Date: Jul. 6, 2023

(54) RESIN COMPOSITION FOR WIRING BOARD MATERIAL, AND PREPREG, RESIN-COATED FILM, RESIN-COATED METAL FOIL, METAL-CLAD LAMINATE, AND WIRING BOARD IN WHICH SAID RESIN COMPOSITION IS USED

(71) Applicant: PANASONIC INTELLECTUAL PROPERTY MANAGEMENT CO., LTD., Osaka (JP)

(72) Inventors: Lin LIN, Osaka (JP); Yuki KITAI, Osaka (JP)

(73) Assignee: PANASONIC INTELLECTUAL PROPERTY MANAGEMENT CO., LTD., Osaka (JP)

(21) Appl. No.: 17/927,795

(22) PCT Filed: Apr. 15, 2021
(86) PCT No.: PCT/JP2021/015571

§ 371 Date: Nov. 25, 2022

(30) Foreign Application Priority Data
May 29, 2020 (JP) 2020-094229
May 29, 2020 (JP) 2020-094230

(51) Int. Cl. C08L 71/08; C08K 7/18; C08K 7/22; C08J 5/24; C08J 7/04; H05K 1/03

(52) U.S. Cl. CPC C08L 71/08; C08K 7/18; C08K 7/22; C08J 5/24; C08J 7/0427; H05K 1/0353; C08L 2207/53; C08J 2371/08

(57) ABSTRACT

A resin composition for wiring board material contains a thermosetting resin and a thermally expandable microcapsule, in which the relative dielectric constant (10 GHz) of a cured product of the resin composition is more than 1.0 and 2.2 or less.

### TECHNICAL FIELD

The present invention relates to a resin composition for wiring board material, and a prepreg, a resin-coated film, a resin-coated metal foil, a metal-clad laminate, and a wiring board obtained using the resin composition.

### BACKGROUND ART

In recent years, in various electronic devices, mounting technique such as higher integration of semiconductor devices to be mounted, higher wiring density, and multi-layering have rapidly progressed along with an increase in the amount of information processed. Board materials for constituting substrates of wiring boards used in various electronic devices are required to have a low dielectric constant and a low dielectric loss tangent to increase the transmission speed of signals and decrease the loss during signal transmission.

Meanwhile, thermally expandable microcapsules are known to be used, for example, for peeling off and the like in a method for manufacturing a package for semiconductor device mounting (Patent Literature 1), but recently it has also been reported that a foaming technique using thermally expandable microcapsules and the like is used to lower the dielectricity. For example, in the technique described in Patent Literature 2, it is said that an additive (core material) with a low dielectric constant can be favorably dispersed in the cured product, bleed out can be suppressed, and a decrease in the dielectric constant of the cured product can be realized by preparing a curable resin composition containing microcapsules in which a core material is encapsulated in a shell in a thermosetting resin.

However, since the well-known foaming technique centered on thermoplastic resins requires various hardware and the like in the foaming process and a large number of resins have a large coefficient of expansion among thermoplastic resins, there are a large number of restrictions to apply thermoplastic resins to printed board materials and it has not been possible to realize the application easily.

In addition, foaming technique is used in board applications in some inventions, such as the technique described in Patent Literature 2, and is considered to be an effective means for obtaining low dielectric properties, but the conventional thermally expandable microcapsules have a problem of poor heat resistance. In other words, it has been found that the thermally expandable microcapsules cannot withstand the curing temperature (higher than 100° C.) and burst during the curing process of thermosetting resins. It has been found through the studies by the present inventors that the cured product of the resin composition for wiring board containing a thermosetting resin cannot be expected to have a dielectricity lowering effect and some properties of the board may be impaired in this case, and the conventional foaming technique is unsuitable for use in wiring boards.

From the above, it has been required to develop a resin composition for wiring board containing a thermosetting resin, in which thermally expandable microcapsules are applied and the cured product of the resin composition exhibits extremely excellent low dielectric properties.

### CITATION LIST

### Patent Literature

Patent Literature 1: WO 2018/026004 A
Patent Literature 2: JP 2017-132899 A

### SUMMARY OF INVENTION

The present invention is made in view of such circumstances, and an object thereof is to provide a resin composition for wiring board material, which can extremely decrease the relative dielectric constant of a cured product thereof while maintaining properties such as heat resistance. Another object of the present invention is to provide a prepreg, a resin-coated film, a resin-coated metal foil, a metal-clad laminate, and a wiring board, which are obtained using the resin composition.

A resin composition for wiring board material according to an aspect of the present invention includes: a thermosetting resin; and a thermally expandable microcapsule, in which a relative dielectric constant (10 GHz) of a cured product of the resin composition is more than 1.0 and 2.2 or less.

### BRIEF DESCRIPTION OF DRAWINGS

FIG. 1 is a schematic sectional view illustrating the configuration of a prepreg according to an embodiment of the present invention.

FIG. 2 is a schematic sectional view illustrating the configuration of a metal-clad laminate according to an embodiment of the present invention.

FIG. 3 is a schematic sectional view illustrating the configuration of a wiring board according to an embodiment of the present invention.

FIG. 4 is a schematic sectional view illustrating the configuration of a resin-coated metal foil according to an embodiment of the present invention.

FIG. 5 is a schematic sectional view illustrating the configuration of a resin film according to an embodiment of the present invention.

### DESCRIPTION OF EMBODIMENTS

The resin composition for wiring board material according to an embodiment of the present invention (hereinafter also simply referred to as a resin composition) contains a thermosetting resin and a thermally expandable microcapsule, and the relative dielectric constant (10 GHz) of a cured product of the resin composition is more than 1.0 and 2.2 or less.

According to the configuration, it is possible to provide a resin composition for wiring board material, which can extremely decrease the relative dielectric constant of a cured product thereof while maintaining properties such as heat resistance. By using the resin composition, it is possible to provide a prepreg, a resin-coated film, a resin-coated metal foil, a metal-clad laminate, and a wiring board, which are equipped with excellent low dielectric properties.

<Relative Dielectric Constant>

The cured product of the resin composition of the present embodiment has a relative dielectric constant (10 GHz) of more than 1.0 and 2.2 or less, and exhibits extremely low dielectric properties compared to conventional thermosetting board materials with low dielectric constant.

The value of relative dielectric constant (Dk) in the present specification is a value obtained by measuring the relative dielectric constant at 10 GHz of a test piece prepared by the method described in Examples later at a temperature of 23° C.±2° C. and a humidity of 50%±5% RH using the cavity perturbation method conforming to ASTM D2520.

In a more preferred embodiment, the relative dielectric constant (10 GHz) of the cured product of the resin composition according to the present embodiment is 1.5 to 2.0.

Although not limited, the dielectric loss tangent (Df) of the cured product of the resin composition according to the present embodiment is preferably about 0.0001 to 0.004, more preferably 0.001 to 0.004. The dielectric loss tangent in the present specification is a value measured by a method similar to that for the relative dielectric constant.

<Density of Cured Product>

The density of a cured product of the resin composition according to the present embodiment is preferably 0.3 to 1.0 g/cm³.

So far, a technique has been reported in which thermally expandable microcapsules are introduced into an insulating substrate in an electronic device to form a thermally expandable insulating substrate in order to suppress the influence of height variations that may exist in the electrodes of electronic parts and circuit boards (see JP 2013-41905 A and the like). Hence, the present inventors have investigated the use of thermally expandable microcapsules as a board material for constituting the substrate of a wiring board used in various electronic devices as described above to achieve weight saving in addition to the low dielectric properties.

However, since the well-known conventional foaming technique centered on thermoplastic resins requires various hardware and the like in the foaming process and a large number of resins have a large coefficient of expansion among thermoplastic resins, there are a large number of restrictions to apply thermoplastic resins to printed board materials and it has not been possible to realize the application easily.

Most conventional thermally expandable microcapsules have a maximum expansion temperature of around 100° C., and in the general curing process to heat thermosetting resins at 100° C. or more for one hour or more, the shell of the thermally expandable microcapsules becomes thinner, and the vaporized volatile substances escape from the thin portion and broken portion of the shell to often cause shrinking of the microcapsules. It has been found through the studies by the present inventors that there is a risk that the cured product of the resin composition for wiring board containing a thermosetting resin may impair some properties of the board including defective molding of the board in this case, and the conventional foaming technique using thermally expandable microcapsules is unsuitable for use in wiring boards.

Hence, the present inventors have found out that weight saving of the board material can be realized by applying thermally expandable microcapsules to a resin composition for wiring board containing a thermosetting resin. Accordingly, the resin composition for wiring board of the present embodiment has an excellent advantage in that the cured product thereof is significantly lighter compared to conventional board materials.

In the present specification, the density of the cured product of the resin composition was measured by the following procedure. First, a cured resin plate having a thickness of 300 μm is cut using a press cutter to obtain an individual piece of 10 cm×10 cm. The weight of the cut individual piece measured using a precision balance is denoted as M (g). The volume V of individual resin piece is calculated by area S (10×10 cm²)×thickness H (0.03 cm). As for the density, the density of individual piece of each resin cured product is calculated using the equation ρ=M/V.

Since the cured product has a density within the above range, it is possible to diminish the weight by a half or more compared to that of conventional printed boards by using the resin composition of the present embodiment as a board material. Since the printed wiring board can be handled in the same way as conventional printed wiring boards obtained using thermosetting resins, special processing is not required, and it is thus considered that the resin composition can greatly contribute to the decreases in weight and thickness of electronic devices including personal portable devices in the future.

Hereinafter, the respective components of the resin composition according to the present embodiment will be specifically described.

<Thermosetting Resin>

The thermosetting resin used in the present embodiment is not particularly limited as long as it is a thermosetting resin that can be used as a wiring board material, but it is preferable to contain at least one selected from the group consisting of a polyphenylene ether compound, a hydrocarbon-based resin, an epoxy resin, a maleimide compound, a phenolic resin, an oxetane resin, a benzoxazine compound, a liquid crystal polymer, and a compound having a polymerizable unsaturated group.

Among these, it is more preferable to use a resin that affords a low dielectric constant, a low dielectric loss tangent, and high heat resistance. Specifically, a polyphenylene ether compound and a hydrocarbon-based resin, a maleimide compound and the like are preferably exemplified.

(Polyphenylene Ether Compound)

As the polyphenylene ether compound, for example, it is preferable to use a terminal-modified polyphenylene ether compound that can exert excellent low dielectric properties when cured, furthermore, it is preferable to use a modified polyphenylene ether compound of which the terminal is modified with a substituent having a carbon-carbon unsaturated double bond.

Examples of the modified polyphenylene ether compound include modified polyphenylene ether compounds represented by the following Formulas (1) to (3).

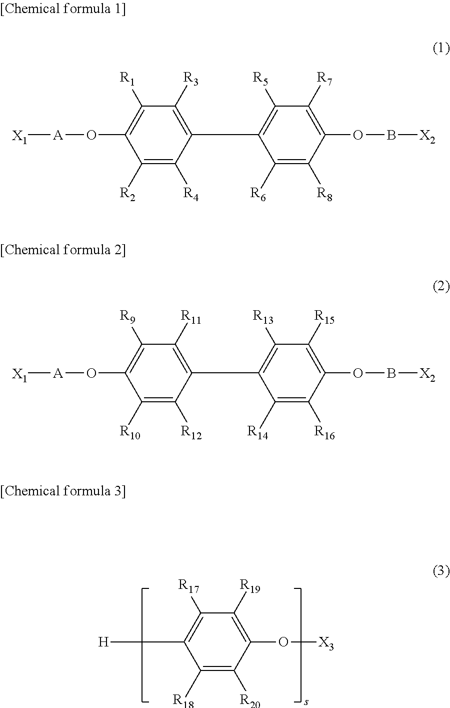

In Formulas (1) to (3), R₁ to R₈, R₉ to R₁₆ and R₁₇ to R₂₀ are independent of one another. In other words, R₁ to R₈, R₉ to R₁₆ and R₁₇ to R₂₀ may be the same group as or different groups from one another. R₁ to R₈, R₉ to R₁₆ and R₁₇ to R₂₀ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

Specific examples of the respective functional groups mentioned above as R₁ to R₈, R₉ to R₁₆ and R₁₇ to R₂₀ include the following.

The alkyl group is not particularly limited, but for example, an alkyl group having 1 to 18 carbon atoms is preferable, and an alkyl group having 1 to 10 carbon atoms is more preferable. Specific examples thereof include a methyl group, an ethyl group, a propyl group, a hexyl group, and a decyl group.

The alkenyl group is not particularly limited, but for example, an alkenyl group having 2 to 18 carbon atoms is preferable, and an alkenyl group having 2 to 10 carbon atoms is more preferable. Specific examples thereof include a vinyl group, an allyl group, and a 3-butenyl group.

The alkynyl group is not particularly limited, but for example, an alkynyl group having 2 to 18 carbon atoms is preferable, and an alkynyl group having 2 to 10 carbon atoms is more preferable. Specific examples thereof include an ethynyl group and a prop-2-yn-1-yl group (propargyl group).

The alkylcarbonyl group is not particularly limited as long as it is a carbonyl group substituted with an alkyl group, but for example, an alkylcarbonyl group having 2 to 18 carbon atoms is preferable, and an alkylcarbonyl group having 2 to 10 carbon atoms is more preferable. Specific examples thereof include an acetyl group, a propionyl group, a butyryl group, an isobutyryl group, a pivaloyl group, a hexanoyl group, an octanoyl group, and a cyclohexylcarbonyl group.

The alkenylcarbonyl group is not particularly limited as long as it is a carbonyl group substituted with an alkenyl group, but for example, an alkenylcarbonyl group having 3 to 18 carbon atoms is preferable, and an alkenylcarbonyl group having 3 to 10 carbon atoms is more preferable. Specific examples thereof include an acryloyl group, a methacryloyl group, and a crotonoyl group.

The alkynylcarbonyl group is not particularly limited as long as it is a carbonyl group substituted with an alkynyl group, but for example, an alkynylcarbonyl group having 3 to 18 carbon atoms is preferable, and an alkynylcarbonyl group having 3 to 10 carbon atoms is more preferable. Specific examples thereof include a propioloyl group.

In Formulas (1) and (2), as described above, A is a structure represented by the following Formula (4) and B is a structure represented by the following Formula (5):

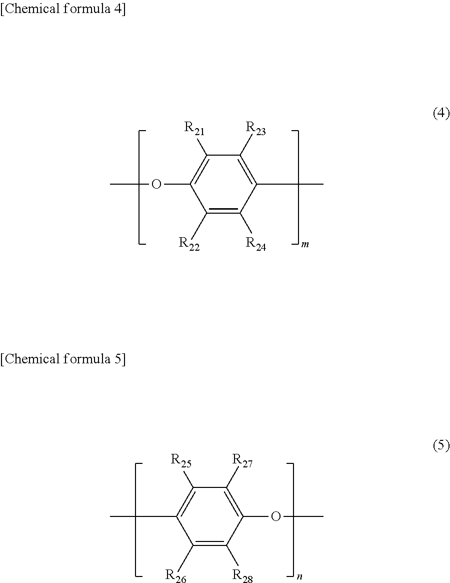

In Formulas (4) and (5), m and n, which are repeating units, each represent an integer 1 to 50.

R₂₁ to R₂₄ and R₂₅ to R₂₈ are independent of one another. In other words, R₂₁ to R₂₄ and R₂₅ to R₂₈ may be the same group as or different groups from one another. In the present embodiment, R₂₁ to R₂₄ and R₂₅ to R₂₈ are a hydrogen atom or an alkyl group.

In Formula (3), s represents an integer 1 to 100.

Furthermore, in Formula (2), Y includes linear, branched or cyclic hydrocarbons having 20 or less carbon atoms. More specifically, Y is, for example, a structure represented by the following Formula (6):

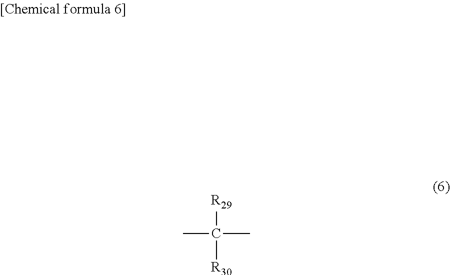

In Formula (6), R₂₉ and R₃₀ each independently represent a hydrogen atom or an alkyl group. Examples of the alkyl group include a methyl group. Examples of the group represented by Formula (6) include a methylene group, a methylmethylene group, and a dimethylmethylene group.

In Formulas (1) to (3), X₁ to X₃ each independently represent, for example, a styrene structure or (meth)acrylate structure represented by the following Formula (7) or (8). X₁ and X₂ may be the same as or different from each other.

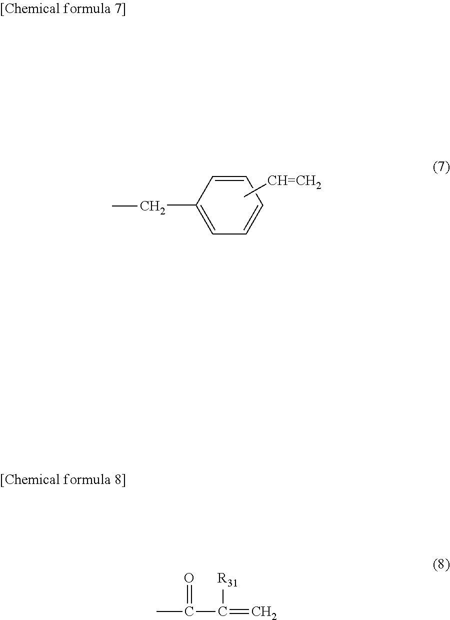

In Formula (8), R₃₁ represents a hydrogen atom or an alkyl group. The alkyl group is not particularly limited, and for example, an alkyl group having 1 to 18 carbon atoms is preferable, and an alkyl group having 1 to 10 carbon atoms is more preferable. Specific examples thereof include a methyl group, an ethyl group, a propyl group, a hexyl group, and a decyl group.

More specific examples of the substituents X₁ to X₃ in the present embodiment include vinylbenzyl groups (ethenylbenzyl groups) such as a p-ethenylbenzyl group and a m-ethenylbenzyl group, a vinylphenyl group, an acrylate group, and a methacrylate group.

By using such modified polyphenylene ether compounds represented by Formulas (1) to (3), it is considered that high Tg and adhesive properties can be improved while low dielectric properties such as low dielectric constant and low dielectric loss tangent and excellent heat resistance are maintained.

The modified polyphenylene ether compounds represented by Formulas (1) to (3) can be used singly or in combination of two or more kinds thereof.

In the present embodiment, the weight average molecular weight (Mw) of the modified polyphenylene ether compound used as a thermosetting resin is not particularly limited, but is, for example, preferably 1000 to 5000, more preferably 1000 to 4000. The weight average molecular weight may be measured by a general molecular weight measuring method, and specific examples thereof include a value measured by gel permeation chromatography (GPC). In a case where the modified polyphenylene ether compound has repeating units (s, m, and n) in the molecule, these repeating units are preferably numerical values such that the weight average molecular weight of the modified polyphenylene ether compound falls within this range.

When the weight average molecular weight of the modified polyphenylene ether compound is within such a range, the excellent low dielectric properties of the polyphenylene ether skeleton are exhibited and a cured product exhibiting not only superior heat resistance but also excellent moldability is afforded. This is considered to be due to the following. Compared with ordinary polyphenylene ether, the modified polyphenylene ether compound has a relatively low molecular weight if the weight average molecular weight thereof is within a range as described above, and thus the heat resistance of the cured product tends to decrease. With regard to this point, it is considered that the modified polyphenylene ether compound according to the present embodiment has a styrene structure or a (meth)acrylate structure at the terminal, and thus a resin composition is obtained which exhibits high reactivity and imparts sufficiently high heat resistance to the cured product thereof. When the weight average molecular weight of the modified polyphenylene ether compound is within such a range, the modified polyphenylene ether compound has a higher molecular weight than styrene or divinylbenzene but has a relatively lower molecular weight than general polyphenylene ether, and thus excellent moldability is also considered to be imparted to the cured product. Therefore, such a modified polyphenylene ether compound is considered to afford a cured product exhibiting not only superior heat resistance but also excellent moldability.

In the modified polyphenylene ether compound used as a thermosetting resin in the present embodiment, the average number of X₁ to X₃ substituents (number of terminal functional groups) at the terminals of the molecule per one molecule of modified polyphenylene ether is not particularly limited. Specifically, the number of terminal functional groups is preferably 1 to 5, more preferably 1 to 3. When the number of terminal functional groups is too small, it tends to be difficult to obtain a cured product exhibiting sufficient heat resistance. When the number of terminal functional groups is too large, the reactivity is too high, and for example, there is a possibility that troubles such as a decrease in storage stability of the resin composition and a decrease in fluidity of the resin composition may occur. In other words, there is a possibility that the use of such a modified polyphenylene ether causes moldability problems in that, for example, molding defects such as voids are generated during multilayer molding by poor fluidity and the like and it is difficult to obtain a highly reliable printed wiring board.

The number of terminal functional groups in the modified polyphenylene ether compound includes a numerical value representing the average value of the substituents per molecule of all modified polyphenylene ether compounds present in 1 mole of the modified polyphenylene ether compound. This number of terminal functional groups can be measured by, for example, measuring the number of hydroxyl groups remaining in the resulting modified polyphenylene ether compound and calculating the decrement from the number of hydroxyl groups in the polyphenylene ether before modification. This decrement from the number of hydroxyl groups in the polyphenylene ether before modification is the number of terminal functional groups. As the method for measuring the number of hydroxyl groups remaining in the modified polyphenylene ether compound, the number of hydroxyl groups remaining in the modified polyphenylene ether compound can be determined by adding a quaternary ammonium salt (tetraethylammonium hydroxide) that associates with a hydroxyl group to a solution of the modified polyphenylene ether compound and measuring the UV absorbance of the mixed solution.

The intrinsic viscosity of the modified polyphenylene ether compound used in the present embodiment is not particularly limited. Specifically, the intrinsic viscosity may be 0.03 to 0.12 dl/g, but is preferably 0.04 to 0.11 dl/g, more preferably 0.06 to 0.095 dl/g. When this intrinsic viscosity is too low, the molecular weight tends to be low, and it tends to be difficult to obtain low dielectric properties such as low dielectric constant and low dielectric loss tangent. When the intrinsic viscosity is too high, the viscosity tends to be high, sufficient fluidity is not obtained, and the moldability of the cured product tends to decrease. Hence, when the intrinsic viscosity of the modified polyphenylene ether compound is within the above range, excellent heat resistance and moldability of the cured product can be realized.

The intrinsic viscosity here is the intrinsic viscosity measured in methylene chloride at 25° C., and is more specifically a value measured in, for example, a 0.18 g/45 ml methylene chloride solution (liquid temperature: 25° C.) using a viscometer. Examples of this viscometer include AVS500 Visco System manufactured by Schott Instruments GmbH.

The method for synthesizing the modified polyphenylene ether compound preferably used in the present embodiment is not particularly limited as long as it can synthesize a modified polyphenylene ether compound of which the terminal is modified with substituents X₁ to X₃ as described above. Specific examples thereof include a method in which polyphenylene ether is reacted with a compound in which substituents X₁ to X₃ are bonded to halogen atoms.

The polyphenylene ether as a starting material is not particularly limited as long as predetermined modified polyphenylene ether can be finally synthesized. Specific examples thereof include those containing polyphenylene ether composed of 2,6-dimethylphenol and at least one of bifunctional phenol and trifunctional phenol and polyphenylene ether such as poly(2,6-dimethyl-1,4-phenylene oxide) as a main component. Bifunctional phenol is a phenol compound having two phenolic hydroxyl groups in the molecule, and examples thereof include tetramethylbisphenol A. Trifunctional phenol is a phenol compound having three phenolic hydroxyl groups in the molecule.

As an example of the method for synthesizing a modified polyphenylene ether compound, for example, in the case of the modified polyphenylene ether compound represented by Formula (2), specifically, a polyphenylene ether as described above and a compound in which substituents X₁ and X₂ are bonded to halogen atoms (compound having substituents X₁ and X₂) are dissolved in a solvent and stirred. By doing so, the polyphenylene ether reacts with the compound having substituents X₁ and X₂, and the modified polyphenylene ether represented by Formula (2) of the present embodiment is obtained.

This reaction is preferably conducted in the presence of an alkali metal hydroxide. It is considered that this reaction proceeds suitably by doing so. This is considered to be because the alkali metal hydroxide functions as a dehydrohalogenating agent, specifically a dehydrochlorinating agent. In other words, it is considered that the alkali metal hydroxide eliminates the hydrogen halide from the phenol group in the polyphenylene ether and the compound having the substituent X and, by doing so, the substituents X₁ and X₂ are bonded to the oxygen atoms of the phenolic group instead of the hydrogen atoms of the phenol group in the polyphenylene ether.

The alkali metal hydroxide is not particularly limited as long as it can act as a dehalogenating agent, and examples thereof include sodium hydroxide. Alkali metal hydroxides are usually used in the form of an aqueous solution, specifically as an aqueous sodium hydroxide solution.

The reaction conditions such as reaction time and reaction temperature vary depending on the compound having substituents X₁ and X₂ and the like, and are not particularly limited as long as they are conditions under which a reaction as described above proceed suitably. Specifically, the reaction temperature is preferably room temperature to 100° C., more preferably 30° C. to 100° C. The reaction time is preferably 0.5 to 20 hours, more preferably 0.5 to 10 hours.

The solvent used during the reaction is not particularly limited as long as it can dissolve the polyphenylene ether and the compound having substituents X₁ and X₂ and does not inhibit the reaction between the polyphenylene ether and the compound having substituents X₁ and X₂. Specific examples thereof include toluene.

The reaction is preferably conducted in the presence of not only an alkali metal hydroxide but also a phase transfer catalyst. In other words, the reaction is preferably conducted in the presence of an alkali metal hydroxide and a phase transfer catalyst. It is considered that the reaction proceeds more suitably by doing so. This is considered to be due to the following. It is considered that this is because a phase transfer catalyst is a catalyst that has a function of taking an alkali metal hydroxide in, is soluble in both the phase of a polar solvent such as water and the phase of a nonpolar solvent such as an organic solvent, and can transfer between these phases. Specifically, in a case where an aqueous sodium hydroxide solution is used as the alkali metal hydroxide and an organic solvent such as toluene that is incompatible with water is used as the solvent, it is considered that even when the aqueous sodium hydroxide solution is added dropwise to the solvent being subjected to the reaction, the solvent and the aqueous sodium hydroxide solution separate from each other and the sodium hydroxide is less likely to migrate to the solvent. In that case, it is considered that the aqueous sodium hydroxide solution added as an alkali metal hydroxide is less likely to contribute to the promotion of the reaction. In contrast, when the reaction is conducted in the presence of an alkali metal hydroxide and a phase transfer catalyst, it is considered that the alkali metal hydroxide migrates to the solvent in the state of being taken in the phase transfer catalyst and the aqueous sodium hydroxide solution is likely to contribute to the promotion of the reaction. For this reason, it is considered that the reaction proceeds more suitably when the reaction is conducted in the presence of an alkali metal hydroxide and a phase transfer catalyst.

The phase transfer catalyst is not particularly limited, but examples thereof include quaternary ammonium salts such as tetra-n-butylammonium bromide.

The resin composition according to the present embodiment preferably contains the modified polyphenylene ether obtained in the above manner as modified polyphenylene ether.

(Hydrocarbon-Based Resin)

As a hydrocarbon-based resin usable in the present embodiment, a polyfunctional vinyl aromatic polymer, a cyclic polyolefin resin, and a hydrocarbon-based resin of vinyl aromatic compound-conjugated diene-based compound copolymer are preferably exemplified. The kind and the like of hydrocarbon-based resin are not particularly limited, but it is preferable to use a hydrocarbon-based resin having a weight average molecular weight of 1,000 to 500,000 considering moldability, appearance, and mechanical properties.

The polyfunctional vinyl aromatic polymer is preferably a polymer containing at least one obtained by polymerizing a polyfunctional vinyl aromatic compound or/and a derivative thereof, is not particularly limited as long as it is a polymer containing a structure derived from a polyfunctional vinyl aromatic compound or/and a derivative thereof, and may be polymers containing structures derived from one or more polyfunctional vinyl aromatic compounds or/and derivatives thereof. The polyfunctional vinyl aromatic compound or/and derivative thereof contains two or more vinyl groups and an aromatic ring as a monocycle or condensed ring, and examples thereof include polymers containing compounds such as divinylbenzene, divinylnaphthalene, 9,10-divinylanthracene, 9,9-bis(4-allyloxyphenyl)fluorene, triallyl trimesate, 1,4-diisopropenylbenzene, and 1,3-diisopropenylbenzene and derivatives thereof. Furthermore, the polyfunctional vinyl aromatic polymer of the present embodiment may be further polymerized with a monovinyl aromatic compound or another compound in addition to the above, or may be a copolymer containing a structure derived from a monovinyl aromatic compound or another compound. The monovinyl aromatic compound contains one vinyl group and an aromatic ring as a monocycle or condensed ring, and examples thereof include styrene compounds in which some of the hydrogen atoms on the aromatic rings of styrene, methylstyrene and the like are substituted with substituents such as an alkyl group; and styrene derivatives. The polyfunctional vinyl aromatic polymer may be a copolymer containing one or more structures derived from monovinyl aromatic compounds and other monomers; or the like.

The cyclic polyolefin resin used in the present embodiment refers to a polyolefin-based resin having a cycloaliphatic main chain in its main chain or side chain or a cycloaliphatic hydrocarbon in its side chain. Examples of the cycloaliphatic hydrocarbon include those containing structures represented by the following Structural Formulas (9) to (17).

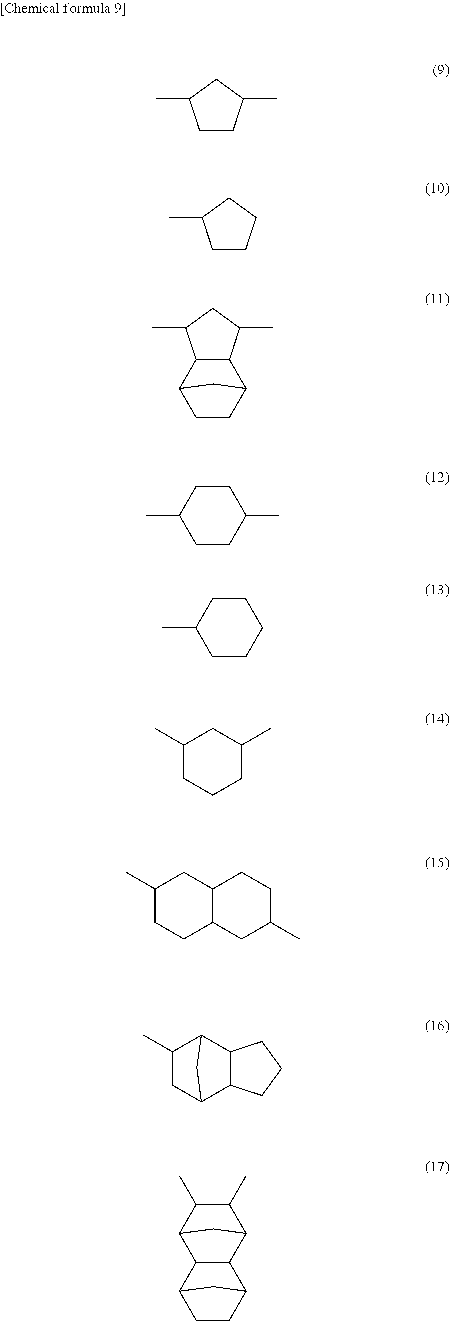

Cyclic polyolefin-based resins include a cycloolefin copolymer (COC) type in which norbornene and ethylene are copolymerized in the presence of a metallocene catalyst, and a COP type that is a metathesis ring-opening polymerization type, and may be used singly or in combination of two or more kinds thereof. Examples of commercially available cyclic polyolefin resins include ZEONEX (registered trademark) and ZEONOR (registered trademark) manufactured by ZEON CORPORATION, ARTON (registered trademark) manufactured by JSR Corporation, APEL (registered trademark) manufactured by Mitsui Chemicals, Inc., and TOPAS (registered trademark) manufactured by Polyplastics Co., Ltd.

The vinyl aromatic compound-conjugated diene-based compound copolymer used in the present embodiment is not particularly limited as long as it is a copolymer containing a structure derived from a vinyl aromatic compound (compound containing one or more vinyl groups and having an aromatic ring) and a structure derived from a conjugated diene-based compound (a compound having a conjugated diene). The copolymer may contain structures derived from one or more kinds of vinyl aromatic compounds and derivatives thereof, or may contain structures derived from one or more kinds of conjugated diene-based compounds. The vinyl aromatic compound-conjugated diene-based compound copolymer may be a partially hydrogenated product. Examples of the vinyl aromatic compound include styrene compounds in which some of the hydrogen atoms on the aromatic rings of styrene, α-methylstyrene, p-methylstyrene and the like are substituted with alkyl groups; and styrene derivatives such as 2-vinylnaphthalene and divinylbenzene. The conjugated diene-based compound is not particularly limited, but examples thereof include 1,3-butadiene, isoprene, 1,3-pentadiene, 1,4-pentadiene, 1,3-heptadiene, cyclopentadiene, 2,3-dimethyl-1,3-butadiene, 1,4-hexadiene, 1,5-hexadiene, 1,3-cyclohexadiene, 1,4-cyclohexadiene, and polymers thereof. Furthermore, in the vinyl aromatic compound-conjugated diene-based compound copolymer, the content of a structural unit derived from the vinyl aromatic compound is preferably 5 to 95 mass %, more preferably 10 to 80 mass %, still more preferably 20 to 50 mass %.

(Maleimide Compound)

As the maleimide compound usable in the present embodiment, any compound having a maleimide group in the molecule can be used without particular limitation. Specific examples of the maleimide compound include a monofunctional maleimide compound having one maleimide group in the molecule, a polyfunctional maleimide compound having two or more maleimide groups in the molecule, and a modified maleimide compound. Examples of the modified maleimide compound include a modified maleimide compound in which a portion of the molecule is modified with an amine compound, a modified maleimide compound in which a portion of the molecule is modified with a silicone compound, and a modified maleimide compound in which a portion of the molecule is modified with an amine compound and a silicone compound.

(Other Resin Components)

In the resin composition of the present embodiment, in addition to the above, a thermosetting resin other than the thermosetting resin described above can be used as a resin component. Examples thereof include a phenol resin, a benzoxazine compound, a liquid crystal polymer, styrene, a styrene derivative, a compound having an acryloyl group in the molecule, a compound having a methacryloyl group in the molecule, a compound having a vinyl group in the molecule, a compound having an allyl group in the molecule, a compound having an acenaphthylene structure in the molecule, and an isocyanurate compound having an isocyanurate group in the molecule. These may be used singly, or may be used in combination of two or more kinds with a thermosetting resin as described above.

Examples of the styrene derivative include bromostyrene and dibromostyrene.

The compound having an acryloyl group in the molecule is an acrylate compound. Examples of the acrylate compound include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include tricyclodecanedimethanol diacrylate.

The compound having a methacryloyl group in the molecule is a methacrylate compound. Examples of the methacrylate compound include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include tricyclodecanedimethanol dimethacrylate.

The compound having a vinyl group in the molecule is a vinyl compound. Examples of the vinyl compound include a monofunctional vinyl compound (monovinyl compound) having one vinyl group in the molecule and a polyfunctional vinyl compound having two or more vinyl groups in the molecule. Examples of the polyfunctional vinyl compound include divinylbenzene, divinylnaphthalene and polybutadiene.

The compound having an allyl group in the molecule is an allyl compound. Examples of the allyl compound include a monofunctional allyl compound having one allyl group in the molecule and a polyfunctional allyl compound having two or more allyl groups in the molecule. Examples of the polyfunctional allyl compound include diallyl phthalate (DAP).

The compound having an acenaphthylene structure in the molecule is an acenaphthylene compound. Examples of the acenaphthylene compound include acenaphthylene, alkylacenaphthylenes, halogenated acenaphthylenes, and phenylacenaphthylenes. Examples of the alkylacenaphthylenes include 1-methylacenaphthylene, 3-methylacenaphthylene, 4-methylacenaphthylene, 5-methylacenaphthylene, 1-ethylacenaphthylene, 3-ethylacenaphthylene, 4-ethylacenaphthylene, and 5-ethylacenaphthylene. Examples of the halogenated acenaphthylenes include 1-chloroacenaphthylene, 3-chloroacenaphthylene, 4-chloroacenaphthylene, 5-chloroacenaphthylene, 1-bromoacenaphthylene, 3-bromoacenaphthylene, 4-bromoacenaphthylene, and 5-bromoacenaphthylene. Examples of the phenylacenaphthylenes include 1-phenylacenaphthylene, 3-phenylacenaphthylene, 4-phenylacenaphthylene, and 5-phenylacenaphthylene. The acenaphthylene compound may be a monofunctional acenaphthylene compound having one acenaphthylene structure in the molecule or a polyfunctional acenaphthylene compound having two or more acenaphthylene structures in the molecule as described above.

The compound having an isocyanurate group in the molecule is an isocyanurate compound. Examples of the isocyanurate compound include a compound further having an alkenyl group in the molecule (alkenyl isocyanurate compound), and examples thereof include a trialkenyl isocyanurate compound such as triallyl isocyanurate (TAIC).

Among the above, for example, a polyfunctional acrylate compound having two or more acryloyl groups in the molecule, a polyfunctional methacrylate compound having two or more methacryloyl groups in the molecule, a polyfunctional vinyl compound having two or more vinyl groups in the molecule, a styrene derivative, an allyl compound having an allyl group in the molecule, a maleimide compound having a maleimide group in the molecule, an acenaphthylene compound having an acenaphthylene structure in the molecule, and an isocyanurate compound having an isocyanurate group in the molecule are preferable.

Any of thermosetting resins as described above may be used singly, or two or more kinds of these may be used in combination.

The thermosetting resin has a weight average molecular weight of preferably 100 to 5,000, more preferably 100 to 4,000, still more preferably 100 to 3,000. When the weight average molecular weight of the thermosetting resin is too low, there is a possibility that the thermosetting resin easily volatilizes from the blended component system of the resin composition. When the weight average molecular weight of the thermosetting resin is too high, there is a possibility that the viscosity of the varnish of the resin composition and the melt viscosity during heat molding become too high. Hence, when the weight average molecular weight of the thermosetting resin is within such a range, a resin composition of which the cured product exhibits superior heat resistance is obtained. The weight average molecular weight may be measured by a general molecular weight measuring method, and specific examples thereof include a value measured by gel permeation chromatography (GPC).

(Ratio)

The thermosetting resin as described above is contained, for example, at preferably 10 to 70 mass %, more preferably 10 to 50 mass % with respect to the total solids in the resin composition.

Although not particularly limited, the resin composition of the present embodiment preferably contains at least one kind of low dielectric resin selected from a polyphenylene ether compound, a hydrocarbon-based resin, or a maleimide compound as a thermosetting resin.

In the case of containing a polyphenylene ether compound, the polyphenylene ether compound is contained at preferably 10 to 90 parts by mass, more preferably 30 to 90 parts by mass with respect to 100 parts by mass of the thermosetting resin. In the case of containing a hydrocarbon-based resin, the hydrocarbon-based resin is contained at preferably 10 to 90 parts by mass, more preferably 30 to 90 parts by mass with respect to 100 parts by mass of the thermosetting resin. In the case of containing a maleimide compound, the maleimide compound is contained at preferably 10 to 90 parts by mass, more preferably 10 to 70 parts by mass with respect to 100 parts by mass of the thermosetting resin.

In a case where the thermosetting resin further contains at least one selected from the group consisting of a phenol resin, an oxetane resin, a benzoxazine compound, a liquid crystal polymer, a compound having a polymerizable unsaturated group, styrene, a styrene derivative, a compound having an acryloyl group in the molecule, a compound having a methacryloyl group in the molecule, a compound having a vinyl group in the molecule, a compound having an allyl group in the molecule, a compound having an acenaphthylene structure in the molecule, and an isocyanurate compound having an isocyanurate group in the molecule in addition to the low dielectric resin, one kind or two or more kinds thereof are preferably contained at 10 to 90 parts by mass with respect to 100 parts by mass of the low dielectric resin.

<Thermally Expandable Microcapsule>

The thermally expandable microcapsules contained in the resin composition of the present embodiment are fine particles that expand (foam) by being heated.

Specifically, the thermally expandable microcapsules of the present embodiment are preferably hollow particles having a core-shell structure in which a liquid compound (core) that is vaporized by heat is covered with a shell containing a thermoplastic resin.

By containing such thermally expandable microcapsules, when the resin composition of the present embodiment is thermally cured, the liquid compound in the thermally expandable microcapsules contained in the resin composition is vaporized by heat, and the capsules expand. After the resin composition is cured, the resin covering the shell of the thermally expandable microcapsules is cured and hardened, and thus the capsules are maintained in an expanded state.

By containing the thermally expandable microcapsules in the resin composition of the present embodiment, it is possible to obtain a cured product equipped with extremely low dielectric properties while maintaining properties such as heat resistance.

The thermoplastic polymer contained in the shell of the thermally expandable microcapsules of the present embodiment is preferably a polymer containing a structure derived from at least one selected from the group consisting of a nitrile-based monomer, a monomer having a carboxyl group, a (meth)acrylate ester-based monomer, a styrene-based monomer, and a monomer having an amide group. In other words, the thermoplastic polymer is preferably a polymer obtained by polymerizing one kind of monomer as described above or two or more kinds of the monomers in combination.

Among these, the thermoplastic polymer is particularly preferably a polymer containing a structure derived from at least one selected from the group consisting of a nitrile-based monomer, a monomer having a carboxyl group, and a (meth)acrylate ester-based monomer.

Specific examples of the monomers include nitrile monomers such as acrylonitrile, methacrylonitrile, α-chloroacrylonitrile, α-ethoxyacrylonitrile, and fumaronitrile; carboxylic acid monomers such as acrylic acid, methacrylic acid, itaconic acid, maleic acid, fumaric acid, and citraconic acid; vinylidene chloride; vinyl acetate; (meth)acrylate esters such as methyl (meth)acrylate, ethyl (meth)acrylate, n-butyl (meth)acrylate, isobutyl (meth)acrylate, t-butyl (meth)acrylate, isobornyl (meth)acrylate, cyclohexyl (meth)acrylate, benzyl (meth)acrylate, and β-carboxyethyl acrylate; styrene monomers such as styrene, α-methylstyrene, and chlorostyrene; amide monomers such as acrylamide, substituted acrylamide, methacrylamide, and substituted methacrylamide, or mixtures thereof.

Among these, it is particularly preferable to use nitrile-based monomers such as acrylonitrile, methacrylonitrile, α-chloroacrylonitrile, α-ethoxyacrylonitrile, and fumaronitrile and a monomer having a carboxyl group such as a methacrylic acid monomer. Thus, thermally expandable microcapsules exhibiting superior heat resistance can be obtained.

The content of the monomer in the thermoplastic polymer composition constituting the shell of the thermally expandable microcapsules is preferably 80 mass % or more. The content of the monomer is more preferably 90 mass % or more.

In order to polymerize monomers as described above singly or in mixture of two or more kinds thereof, it is preferable to use the monomers concurrently with a polymerizable monomer having two or more polymerizable double bonds or a crosslinking agent.

Examples of the polymerizable monomer or crosslinking agent include aromatic divinyl compounds such as divinylbenzene and divinylnaphthalene; allyl methacrylate, triacryl formal, triallyl isocyanate, ethylene glycol di(meth)acrylate, diethylene glycol di(meth)acrylate, triethylene glycol di(meth)acrylate, 1,4-butanediol di(meth)acrylate, 1,9-nonanediol di(meth)acrylate, 1,10-decanediol di(meth)acrylate, PEG #200 di(meth)acrylate, PEG #400 di(meth)acrylate, PEG #600 di(meth)acrylate, neopentyl dalycol di(meth)acrylate, 1,4-butanediol dimethacrylate, 1,6-hexanediol di(meth)acrylate, 1,9-nonanediol di(meth)acrylate, trimethylolpropane trimethacrylate, glycerin dimethacrylate, dimethylol-tricyclodecane diacrylate, pentaerythritol tri(meth)acrylate, pentaerythritol tetraacrylate, dipentaerythritol hexaacrylate, neopentyl glycol acrylate benzoate, trimethylolpropane acrylate benzoate, 2-hydroxy-3-acryloyloxypropyl methacrylate, neopentyl glycol hydroxypivalate diacrylate, ditrimethylolpropane tetraacrylate, and 2-butyl-2-ethyl-1,3-propanediol diacrylate. These may be used singly or in combination of two or more kinds thereof.

The amount of the polymerizable monomer or crosslinking agent blended is preferably about 0.01 to 5 mass % in the thermoplastic polymer composition forming the shell.

In order to obtain the thermoplastic polymer by polymerizing monomers as described above, a polymerization initiator may be appropriately blended. The polymerization initiator is not particularly limited as long as it does not inhibit the effects of the present invention, and for example, polymerization initiators such as a peroxide and an azo compound can be used. Such a polymerization initiator may be appropriately selected depending on the monomers to be used.

Next, the liquid compound that serves as the core in the thermally expandable microcapsules of the present embodiment will be described.

The liquid compound used in the present embodiment is not particularly limited as long as it is vaporized by heat, but is preferably a liquid compound having a boiling point that is equal to or less than the softening temperature of the thermoplastic polymer. In other words, the liquid compound used in the present embodiment is preferably a compound that vaporizes into a gaseous state at a temperature that is equal to or less than the softening point of the thermoplastic polymer constituting the shell of the thermally expandable microcapsule.

As a specific liquid compound, for example, it is preferable to contain at least one selected from the group consisting of a hydrocarbon-based compound, a hydrogen halide-based compound, an alcohol-based compound, an ether-based compound, and a ketone-based compound.

Among these, liquid compounds with low boiling points such as propane, propylene, butene, normal butane, isobutane, isopentane, neopentane, normal pentane, normal hexane, isohexane, heptane, octane, petroleum ether, halomethanes, and tetraalkylsilane, or azodicarbonamide that is thermally decomposed by heating into a gaseous state, and the like are preferably exemplified. The liquid compound of the present embodiment can be appropriately selected from the compounds as described above depending on the temperature range in which the thermally expandable microcapsules are desired to expand (foam), and the like.

In the thermally expandable microcapsules of the present embodiment, it is preferable that the shell does not dissolve in the liquid compound. As the thermoplastic polymer contained in the shell as described above does not dissolve in the liquid compound, there is an advantage that the liquid compound can be enclosed in the shell, microspheres can be formed, and sufficient foaming performance can be imparted.

The resin composition of the present embodiment is for wiring board materials, and is thus used for the purpose of fabricating a board by thermally curing a thermosetting resin. Therefore, it is preferable that the thermally expandable microcapsules expand (foam) in the temperature range for thermally curing the resin composition, and thus the maximum thermal expansion temperature of the thermally expandable microcapsules is preferably 100° C. to 280° C. More preferably, the maximum thermal expansion temperature is 150° C. to 260° C., still more preferably 180° C. to 230° C.

In the case of subjecting thermally expandable microcapsules having a maximum thermal expansion temperature of less than 100° C. to a heat treatment at a high temperature for a long time, problems such as shrinkage of the thermally expandable microcapsules due to outgassing and the like occur since the temperature is considerably lower than the curing temperature of the resin. On the other hand, in the case of thermally expandable microcapsules having a maximum thermal expansion temperature of more than 280° C., it is considered that foaming cannot be performed at a high expansion ratio and there is thus a possibility that a cured product inferior in low dielectric properties is obtained.

It is preferable that the average thickness of the shell of the thermally expandable microcapsules is about 1 to 8 μm. It is considered that breakage and the like during expansion can be further suppressed when the thermally expandable microcapsules have a shell having such a thickness. It is preferable that the volume of the thermally expandable microcapsules at maximum expansion at the maximum thermal expansion temperature is 3 times or more the volume of the thermally expandable microcapsules at room temperature (25° C.). It is considered that excellent low dielectric properties can be thus obtained more reliably.

It is preferable that the thermally expandable microcapsules of the present embodiment can maintain the expansion volume at maximum expansion, the expansion volume being 3 times or more the volume at room temperature (25° C.), for 10 minutes or more. As the expansion volume can be maintained for such a certain time or longer, the expanded state can be maintained during curing of the resin composition, and it is thus possible to maintain the expanded state as it is even after curing is completed. It is considered that the capsules can be thus prevented from bursting and swelling during molding in the case of molding a board using the resin composition of the present embodiment, and the like.

The content of thermally expandable microcapsules as described above in the resin composition of the present embodiment is preferably about 1 to 50 parts by mass with respect to 100 parts by mass of the resin components including the thermosetting resin. The content is more preferably 10 to 30 parts by mass. In a case where the thermosetting resin includes at least one low dielectric resin selected from a polyphenylene ether compound, a hydrocarbon resin, or a maleimide compound, the thermally expandable microcapsules are preferably contained at 1 to 50 parts by mass with respect to 100 parts by mass of these low dielectric resins.

The average particle size of the thermally expandable microcapsules at room temperature (25° C.) is not particularly limited, but the volume-based cumulative 50% particle size (D50) is preferably about 1 to 100 μm. It is considered that there is thus an advantage that the strength of the shell is sufficient during foaming. The true specific gravity of the thermally expandable microcapsules at room temperature (25° C.) is not particularly limited, but is preferably about 0.01 to 0.5.

The true specific gravity in the present embodiment is a value measured by a liquid displacement method (displacing liquid: isopropyl alcohol).

The expansion volume ratio is a value obtained by placing the thermally expandable microcapsules of the present embodiment in an oven, heating the thermally expandable microcapsules for 2 minutes at the expansion temperature (foaming temperature), measuring the true specific gravity of the expanded thermally expandable microcapsules at this time, and dividing the true specific gravity of the expanded microcapsules by the true specific gravity of the thermally expandable microcapsules as a starting material.

The thermally expandable microcapsules of the present embodiment can be produced by a conventionally used method for producing thermally expandable microcapsules.

As the thermally expandable microcapsules used in the resin composition of the present embodiment, commercially available ones can also be used, and examples thereof include “EML-101”, “EM403”, and “EM504” manufactured by SEKISUI CHEMICAL CO., LTD., “920DU80”, “920DU120”, and “980DU120” manufactured by Japan Fillite Co., Ltd., “F-190D”, “F-230D”, “F-260D” and “F-80DE” manufactured by MATSUMOTO YUSHI-SEIYAKU CO., LTD., and “H850D” manufactured by KUREHA CORPORATION.

<Other Components>

The resin composition according to the present embodiment may further contain other components in addition to the thermosetting resin component and the thermally expandable microcapsules.

For example, the resin composition according to the present embodiment may further contain a filler. The filler is not particularly limited and includes those added to enhance the heat resistance and flame retardancy of the cured product of a resin composition. Heat resistance, flame retardancy, and the like can be further enhanced by containing a filler. Specific examples of the filler include metal oxides such as silica such as spherical silica, alumina, titanium oxide, and mica; metal hydroxides such as aluminum hydroxide and magnesium hydroxide; talc; aluminum borate; barium sulfate; and calcium carbonate. As the filler, among these, silica, mica and talc are preferable and spherical silica is more preferable. The fillers may be used singly or in combination of two or more kinds thereof. As the filler, a filler may be used as it is, but one subjected to a surface treatment with an epoxysilane-type, vinylsilane-type, methacrylsilane-type, or aminosilane-type silane coupling agent may be used. The silane coupling agent may be used by being added to the filler by an integral blend method instead of the method of previously treating the surface of the filler with the silane coupling agent.

In the case of containing a filler, the content of the filler is preferably 1 to 300 parts by mass, more preferably 50 to 200 parts by mass with respect to 100 parts by mass of the sum of the resin components.

The resin composition of the present embodiment may further contain a flame retardant, and examples of the flame retardant include halogen-based flame retardants such as a brominated flame retardant; and phosphorus-based flame retardants. Specific examples of the halogen-based flame retardants include brominated flame retardants such as pentabromodiphenyl ether, octabromodiphenyl ether, decabromodiphenyl ether, tetrabromobisphenol A and hexabromocyclododecane; and chlorinated flame retardants such as chlorinated paraffin. Specific examples of phosphorus-based flame retardants include phosphate esters such as a condensed phosphate ester and a cyclic phosphate ester, phosphazene compounds such as a cyclic phosphazene compound, phosphinate salt-based flame retardants such as metal phosphinates such as aluminum dialkylphosphinate, melamine-based flame retardants such as melamine phosphate and melamine polyphosphate, and phosphine oxide compounds having a diphenylphosphine oxide group. As the flame retardant, the exemplified flame retardants may be used singly or in combination of two or more kinds thereof.

The resin composition according to the present embodiment may further contain various additives in addition to those described above. Examples of the additives include antifoaming agents such as a silicone-based antifoaming agent and an acrylate ester-based antifoaming agent, a heat stabilizer, an antistatic agent, an ultraviolet absorber, a dye and a pigment, a lubricant, and dispersing agents such as a wetting and dispersing agent.

The resin composition according to the present embodiment may further contain a reaction initiator. The curing reaction may proceed by the resin components only, but a reaction initiator may be added since there is a case where it is difficult to raise the temperature until curing proceeds depending on the process conditions. The reaction initiator is not particularly limited as long as it can promote the curing reaction of the thermosetting resin as described above. Specific examples thereof include oxidizing agents such as α,α′-bis(t-butylperoxy-m-isopropyl)benzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropyl monocarbonate, and azobisisobutyronitrile. A metal carboxylate and the like can be used concurrently, if necessary. By doing so, the curing reaction can be further promoted. Among these, α,α′-bis(t-butylperoxy-m-isopropyl)benzene is preferably used. α,α′-Bis(t-butylperoxy-m-isopropyl)benzene has a relatively high reaction initiation temperature, thus can suppress the promotion of the curing reaction at the time point at which curing is not required, for example, during drying of prepregs, and can suppress a decrease in storage stability of the resin composition. Furthermore, α,α′-bis(t-butylperoxy-m-isopropyl)benzene exhibits low volatility, thus does not volatilize during drying or storage of prepregs, films and the like, and exhibits favorable stability. The reaction initiators may be used singly or in combination of two or more kinds thereof. As the content of the reaction initiator, the reaction initiator is used so that the added amount thereof is preferably 0.1 to 20 parts by mass with respect to 100 parts by mass of the sum of the resin components.

(Prepreg, resin-coated film, metal-clad laminate, circuit board, and resin-coated metal foil) Next, a prepreg for wiring board, a metal-clad laminate, a wiring board, and a resin-coated metal foil obtained using the resin composition of the present embodiment will be described. The reference numerals in each of the drawings denote the following: 1: prepreg, 2: resin composition or semi-cured product of resin composition, 3: fibrous substrate, 4: thermally expandable microcapsule, 11: metal-clad laminate, 12: insulating layer, 13: metal foil, 14: wiring, 21: wiring board, 31: resin-coated metal foil, 32, 42: resin layer, 41: resin-coated film, 43: support film.

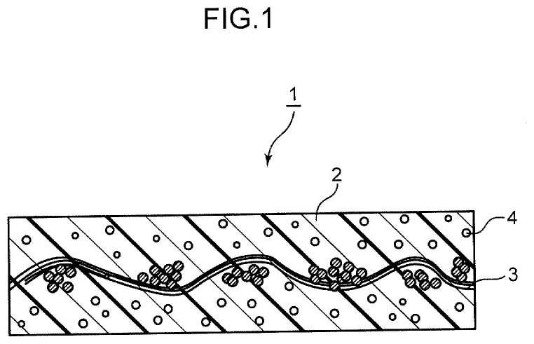

FIG. 1 is a schematic sectional view illustrating an example of a prepreg 1 according to an embodiment of the present invention.

The prepreg 1 according to the present embodiment includes the resin composition containing the thermally expandable microcapsules 4 or a semi-cured product 2 of the resin composition; and a fibrous substrate 3 as illustrated in FIG. 1. The prepreg 1 includes one in which the fibrous substrate 3 is present in the resin composition or semi-cured product 2 thereof. In other words, the prepreg 1 includes the resin composition or semi-cured product thereof; and the fibrous substrate 3 present in the resin composition or semi-cured product 2 thereof.

In the present embodiment, the “semi-cured product” is one in a state in which the resin composition is partially cured so as to be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, semi-curing includes the state between after the viscosity starts to increase and before the resin composition is completely cured.

The prepreg obtained using the resin composition according to the present embodiment may include a semi-cured product of the resin composition as described above, or may include the uncured resin composition itself. In other words, the prepreg may be a prepreg including a semi-cured product of the resin composition (the resin composition in B stage) and a fibrous substrate, or may be a prepreg including the resin composition before curing (the resin composition in A stage) and a fibrous substrate. Specific examples of the prepreg include those in which a fibrous substrate is present in the resin composition. The resin composition or semi-cured product thereof may be one obtained by heating and drying the resin composition.

When the prepreg and the resin-coated metal foil, metal-clad laminate and the like to be described later are fabricated, the resin composition according to the present embodiment is often prepared in the form of a varnish and used as a resin varnish. Such a resin varnish is prepared, for example, as follows.

First, the respective components that can be dissolved in an organic solvent, such as a thermosetting resin and a reaction initiator, are put into an organic solvent and dissolved. At this time, heating may be performed if necessary. After that, components that do not dissolve in an organic solvent, thermally expandable microcapsules, inorganic fillers and the like are added, and dispersion is performed until a predetermined dispersed state is obtained using a ball mill, a bead mill, a planetary mixer, a roll mill or the like if necessary, whereby a varnish-like resin composition is prepared. The organic solvent used in this embodiment is not particularly limited as long as it dissolves the modified polyphenylene ether compound, the maleimide compound, the styrene-butadiene copolymer and the like and does not inhibit the curing reaction. Specific examples thereof include toluene, methyl ethyl ketone, cyclohexanone and propylene glycol monomethyl ether acetate. These may be used singly or two or more kinds thereof may be used concurrently.

Examples of the method for fabricating the prepreg 1 of the present embodiment using the varnish-like resin composition of the present embodiment include a method in which the fibrous substrate 3 is impregnated with the resin composition 2 in the form of a resin varnish and then drying is performed.

Specific examples of the fibrous substrate used in fabrication of the prepreg include glass cloth, aramid cloth, polyester cloth, LCP (liquid crystal polymer) nonwoven fabric, glass nonwoven fabric, aramid nonwoven fabric, polyester nonwoven fabric, pulp paper, and linter paper. When glass cloth is used, a laminate having excellent mechanical strength is obtained, and flattened glass cloth is particularly preferable. The glass cloth used in the present embodiment is not particularly limited, but examples thereof include glass cloth with low dielectric constant such as E glass, S glass, NE glass, Q glass, L glass, and L2 glass. Specifically, the flattening can be carried out, for example, by continuously pressing the glass cloth with press rolls at an appropriate pressure to flatten the yarn. As for the thickness of the fibrous substrate, for example, a fibrous substrate having a thickness of 0.01 to 0.3 mm can be generally used.

Impregnation of the fibrous substrate 3 with the resin varnish (resin composition 2) is performed by dipping, coating, or the like. This impregnation can be repeated multiple times if necessary. At this time, it is also possible to repeat impregnation using a plurality of resin varnishes having different compositions and concentrations, and adjust the composition (content ratio) and resin amount to the finally desired values.

The fibrous substrate 3 impregnated with the resin varnish (resin composition 2) is heated under desired heating conditions, for example, at 80° C. or more and 180° C. or less for 1 minute or more and 10 minutes or less. By heating, the solvent is volatilized from the varnish and the solvent is diminished or removed to obtain the prepreg 1 before curing (in A stage) or in a semi-cured state (B stage).

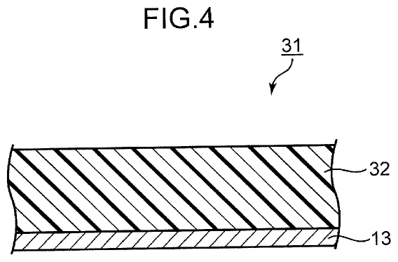

As illustrated in FIG. 4, a resin-coated metal foil 31 of the present embodiment has a configuration in which a resin layer 32 containing the resin composition described above or a semi-cured product of the resin composition; and a metal foil 13 are laminated. In other words, the resin-coated metal foil of the present embodiment may be a resin-coated metal foil including a resin layer containing the resin composition before curing (the resin composition in A stage); and a metal foil, or may be a resin-coated metal foil including a resin layer containing a semi-cured product of the resin composition (the resin composition in B stage); and a metal foil.

Examples of the method for fabricating such a resin-coated metal foil 31 include a method in which a resin composition in the form of a resin varnish as described above is applied to the surface of the metal foil 13 such as a copper foil and then dried. Examples of the application method include a bar coater, a comma coater, a die coater, a roll coater, and a gravure coater.

As the metal foil 13, metal foils used in metal-clad laminates, wiring boards and the like can be used without limitation, and examples thereof include copper foil and aluminum foil.

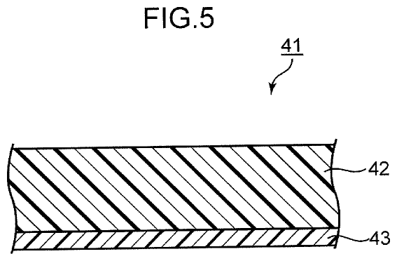

As illustrated in FIG. 5, a resin-coated film 41 of the present embodiment has a configuration in which a resin layer 42 containing the resin composition described above or a semi-cured product of the resin composition; and a film supporting substrate 43 are laminated. In other words, the resin-coated film of the present embodiment may be a resin-coated film including the resin composition before curing (the resin composition in A stage); and a film supporting substrate, or may be a resin-coated film including a semi-cured product of the resin composition (the resin composition in B stage); and a film supporting substrate.

As the method for fabricating such a resin-coated film 41, for example, a resin composition in the form of a resin varnish as described above is applied to the surface of the film supporting substrate 43, and then the solvent is volatilized from the varnish and diminished or removed, whereby a resin-coated film before curing (in A stage) or in a semi-cured state (B stage) can be obtained.

Examples of the film supporting substrate include electrical insulating films such as a polyimide film, a PET (polyethylene terephthalate) film, a polyester film, a poly(parabanic acid) film, a polyether ether ketone film, a polyphenylene sulfide film, an aramid film, a polycarbonate film, and a polyarylate film.

In the resin-coated film and resin-coated metal foil of the present embodiment, the resin composition or semi-cured product thereof may be one obtained by drying or heating and drying the resin composition as in the prepreg described above.

The thickness and the like of the metal foil 13 and the film supporting substrate 43 can be appropriately set depending on the desired purpose. For example, as the metal foil 13, a metal foil having a thickness of about 0.2 to 70 μm can be used. In a case where the thickness of metal foil is, for example, 10 μm or less, the metal foil may be a carrier-attached copper foil including a release layer and a carrier in order to improve handling properties. The application of the resin varnish to the metal foil 13 and the film supporting substrate 43 is performed by coating or the like, and this can be repeated multiple times if necessary. At this time, it is also possible to repeat coating using a plurality of resin varnishes having different compositions and concentrations, and adjust the composition (content ratio) and resin amount to the finally desired values.

Drying or heating and drying conditions in the fabrication method of the resin-coated metal foil 31 and the resin film 41 are not particularly limited, but a resin composition in the form of a resin varnish is applied to the metal foil 13 and the film supporting substrate 43, and then heating is performed under desired heating conditions, for example, at 80° C. to 170° C. for about 1 to 10 minutes to volatilize the solvent from the varnish and diminish or remove the solvent, whereby the resin-coated metal foil 31 and resin film 41 before curing (in A stage) or in a semi-cured state (B stage) are obtained.

The resin-coated metal foil 31 and resin film 41 may include a cover film and the like if necessary. By including a cover film, it is possible to prevent foreign matter from entering. The cover film is not particularly limited as long as it can be peeled off without damaging the form of the resin composition, and for example, a polyolefin film, a polyester film, a TPX film, films formed by providing a release agent layer on these films, and paper obtained by laminating these films on a paper substrate can be used.

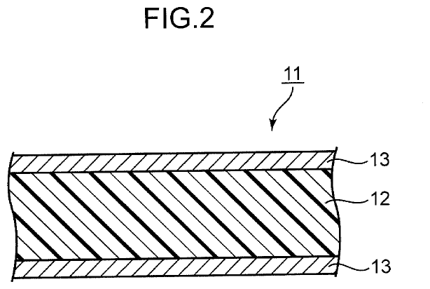

As illustrated in FIG. 2, a metal-clad laminate 11 of the present embodiment includes an insulating layer 12 containing a cured product of the resin composition described above or a cured product of the prepreg described above; and a metal foil 13. As the metal foil 13 used in the metal-clad laminate 11, a metal foil similar to the metal foil 13 described above can be used.

The metal-clad laminate 13 of the present embodiment can also be fabricated using the resin-coated metal foil 31 or resin film 41 described above.

As the method for fabricating a metal-clad laminate using the prepreg 1, resin-coated metal foil 31, or resin film 41 obtained in the manner described above, one or a plurality of prepregs 1, resin-coated metal foils 31, or resin films 41 are superimposed one on another, and the metal foils 13 such as copper foil are further superimposed on both upper and lower sides or on one side, and this is laminated and integrated by heating and pressing, whereby a double-sided metal-clad or single-sided metal-clad laminate can be fabricated. The heating and pressing conditions can be appropriately set depending on the thickness of the laminate to be fabricated, the kind of the resin composition, and the like, but for example, the temperature may be set to 170° C. to 220° C., the pressure may be set to 1.5 to 5.0 MPa, and the time may be set to 60 to 150 minutes.

The metal-clad laminate 11 may be fabricated by forming a film-like resin composition on the metal foil 13 without using the prepreg 1 or the like and performing heating and pressing.

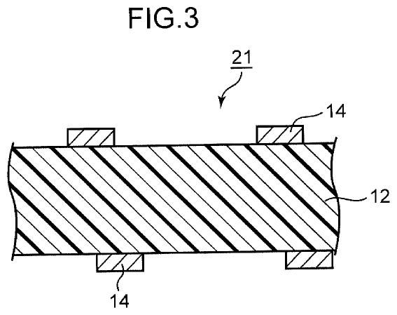

As illustrated in FIG. 3, a wiring board 21 of the present embodiment includes wiring 14 and an insulating layer 12 containing a cured product of the resin composition described above or a cured product of the prepreg described above.

The resin composition of the present embodiment is suitably used as a material for an interlayer insulating layer of a wiring board. As the method for fabricating the wiring board 21, for example, the metal foil 13 on the surface of the metal-clad laminate 11 obtained above is etched to form a circuit (wiring), whereby the wiring board 21 having a conductor pattern (wiring 14) provided as a circuit on the surface of a laminate can be obtained. Examples of the circuit forming method include circuit formation by a semi additive process (SAP) or a modified semi additive process (MSAP) in addition to the method described above.

The prepreg, resin-coated film, and resin-coated metal foil obtained using the resin composition for wiring board material of the present embodiment are extremely useful in industrial applications since the cured products thereof exhibit extremely excellent low dielectric properties, high Tg, high heat resistance and the like. The metal-clad laminate and wiring board obtained by curing these exhibit high heat resistance, high Tg, and extremely excellent low dielectric properties.

Hereinafter, the present invention will be described more specifically with reference to Examples, but the scope of the present invention is not limited to these.

### EXAMPLES

First, the components used in preparation of the resin composition in the present Example will be described.

<Thermosetting Resin>

Modified PPE-1: Bifunctional Vinylbenzyl Modified PPE (Mw: 1900)

First, modified polyphenylene ether (modified PPE-1) was synthesized. The average number of phenolic hydroxyl groups at the terminals of the molecule per one molecule of polyphenylene ether is denoted as the number of terminal hydroxyl groups.

Modified polyphenylene ether 1 (modified PPE-1) was obtained by reacting polyphenylene ether with chloromethylstyrene. Specifically, first, into a 1-liter three-necked flask equipped with a temperature controller, a stirrer, a cooling facility, and a dropping funnel, 200 g of polyphenylene ether (SA90 manufactured by SABIC Innovative Plastics Co., Ltd., intrinsic viscosity (IV): 0.083 dl/g, number of terminal hydroxyl groups: 1.9, weight molecular weight Mw: 1700), 30 g of a mixture of p-chloromethylstyrene and m-chloromethylstyrene at a mass ratio of 50:50 (chloromethylstyrene: CMS manufactured by Tokyo Chemical Industry Co., Ltd.), 1.227 g of tetra-n-butylammonium bromide as a phase transfer catalyst, and 400 g of toluene were put and stirred. Then, the mixture was stirred until polyphenylene ether, chloromethylstyrene, and tetra-n-butylammonium bromide were dissolved in toluene. At that time, the mixture was gradually heated until the liquid temperature finally reached 75° C. Then, an aqueous sodium hydroxide solution (20 g of sodium hydroxide/20 g of water) was added dropwise to the solution as an alkali metal hydroxide over 20 minutes. After that, the resulting mixture was further stirred at 75° C. for 4 hours. Next, the contents in the flask were neutralized with 10 mass % hydrochloric acid, and then a large amount of methanol was added. A precipitate was thus generated in the liquid in the flask. In other words, the product contained in the reaction mixture in the flask was reprecipitated. Then, this precipitate was taken by filtration and washed three times with a liquid mixture of methanol and water at a mass ratio of 80:20, and then dried at 80° C. under reduced pressure for 3 hours.

The obtained solid was analyzed by ¹H-NMR (400 MHz, CDCl₃, TMS). As a result of NMR measurement, a peak attributed to ethenylbenzyl was confirmed at 5 to 7 ppm. This confirmed that the obtained solid was polyphenylene ether in which the terminals of the molecule were ethenylbenzylated.

The molecular weight distribution of modified polyphenylene ether was measured by GPC. Then, the weight average molecular weight (Mw) was calculated from the obtained molecular weight distribution, and as a result, Mw was 1,900.

The number of terminal functional in the modified polyphenylene ether was measured as follows.

First, the modified polyphenylene ether was accurately weighed. The weight at that time is denoted as X (mg). Then, the weighed modified polyphenylene ether was dissolved in 25 mL of methylene chloride, 100 μL of a 10 mass % ethanol solution of tetraethylammonium hydroxide (TEAH) (TEAH:ethanol (volume ratio)=15:85) was added to the solution, and then the absorbance (Abs) at 318 nm was measured using a UV spectrophotometer (UV-1600 manufactured by Shimadzu Corporation). Then, the number of terminal hydroxyl groups in the modified polyphenylene ether was calculated from the measurement results using the following equation.

Residual OH amount(μmol/g)=[(25×Abs)/(ε×OPL×X)]×106

In this embodiment, ε denotes the extinction coefficient and is 4700 L/mol·cm. OPL denotes the cell optical path length and is 1 cm.

From the fact that the calculated residual OH amount (number of terminal hydroxyl groups) in the modified polyphenylene ether is almost zero, it was found that the hydroxyl groups in polyphenylene ether before modification were almost modified. From this fact, it was found that the decrement from the number of terminal hydroxyl groups in the polyphenylene ether before modification is the number of terminal hydroxyl groups in the polyphenylene ether before modification. In other words, it was found that the number of terminal hydroxyl groups in the polyphenylene ether before modification is the number of terminal functional groups in the modified polyphenylene ether. That is, the number of terminal functional was 1.8. This polyphenylene ether is denoted as “modified PPE-1”.

Modified PPE-2: Monofunctional Vinylbenzyl Modified PPE (Mw: 3300)

Modified PPE-2 was synthesized in the same manner as in the synthesis of the modified PPE1 except that polyphenylene ether to be described later was used as polyphenylene ether and the conditions were set to the conditions described later.

The polyphenylene ether used was polyphenylene ether having the structure represented by Formula (5) (SA120 manufactured by SABIC Innovative Plastics Co., Ltd., intrinsic viscosity (IV): 0.125 dl/g, number of terminal hydroxyl groups: 1).

Next, synthesis was performed in the same manner as in the synthesis of modified PPE1 except that 200 g of the polyphenylene ether (SA120), 15 g of CMS, and 0.92 g of a phase transfer catalyst (tetra-n-butylammonium bromide) were used in the reaction of polyphenylene ether with chloromethylstyrene and an aqueous sodium hydroxide solution (sodium hydroxide 10 g/water 10 g) was used instead of the aqueous sodium hydroxide solution (sodium hydroxide 20 g/water 20 g).

The obtained solid was then analyzed by ¹H-NMR (400 MHz, CDCl₃, TMS). As a result of NMR measurement, a peak attributed to ethenylbenzyl was confirmed at 5 to 7 ppm. This confirmed that the obtained solid was modified polyphenylene ether having a group represented by Formula (1) at the terminals of the molecule. Specifically, the obtained solid was confirmed to be ethenylbenzylated polyphenylene ether.

The number of terminal functional in the modified polyphenylene ether was measured in the same manner as above. As a result, the number of terminal functional was 0.9.

The intrinsic viscosity (IV) of the modified polyphenylene ether in methylene chloride at 25° C. was measured by a method similar to the method described above. As a result, the intrinsic viscosity (IV) of the modified polyphenylene ether was 0.125 dl/g.
DVB: Divinylbenzene (manufactured by NIPPON STEEL CORPORATION)
TAIC: Triallyl isocyanurate (manufactured by Nihon Kasei Co., Ltd.)
B-1000: Polybutadiene oligomer (manufactured by Nippon Soda Co., Ltd.)

<Thermally Expandable Microcapsule>
EM403 (manufactured by SEKISUI CHEMICAL CO., LTD., thermal expansion start temperature: 150° C. to 170° C., maximum expansion temperature: 200° C. to 220° C.)
EM504 (manufactured by SEKISUI CHEMICAL CO., LTD., thermal expansion start temperature: 160° C. to 180° C., maximum expansion temperature: 190° C. to 210° C.)
980DU120 (manufactured by Japan Fillite Co., Ltd., thermal expansion start temperature: 158° C. to 173° C., maximum expansion temperature: 215° C. to 235° C.)
F-230D (manufactured by MATSUMOTO YUSHI-SEIYAKU CO., LTD., thermal expansion start temperature: 180° C. to 190° C., maximum expansion temperature: 220° C. to 240° C.)
F-260D (manufactured by MATSUMOTO YUSHI-SEIYAKU CO., LTD., thermal expansion start temperature: 190° C. to 200° C., maximum expansion temperature: 250° C. to 260° C.)

<Other Components>

(Reaction Initiator)
Peroxide: “PERBUTYL P”, 1,3-bis(butylperoxyisopropyl)benzene (manufactured by NOF CORPORATION)

(Inorganic Filler)
SO-C2: Spherical silica (manufactured by ADMATECHS COMPANY LIMITED) (Blowing agent)
Neocellborn N #5000: Chemical blowing agent (manufactured by EIWA CHEMICAL IND. CO., LTD.)
Spangcell ST #44: Chemical blowing agent (manufactured by EIWA CHEMICAL IND. CO., LTD.)

### Examples 1 to 15 and Comparative Examples 1 to 5

[Preparation Method]

(Resin Varnish)

First, each component, that is, modified PPE and another thermosetting resin were added to toluene at the blending proportion described in Tables 1 and 2 so that the solid concentration was 50 mass %, and mixed and dissolved by performing heating and stirring at 80° C. for 60 minutes. The mixture was allowed to cool to 25 degrees, then thermally expandable microcapsules, peroxides, inorganic fillers and the like were added, and stirring and dispersion using a bead mill were performed to obtain a resin varnish (toluene solution resin varnish).

(Resin-Coated Copper Foil)

Resin-coated copper foils (RCC) were fabricated using the resin varnishes of Examples and Comparative Examples prepared above, and used in the subsequent evaluation.

A copper foil (“FV-WS” manufactured by Furukawa Electric Co., Ltd.) having a thickness of 18 μm or 36 μm was used for the RCC. Then, the resin varnish was applied to the surface of the copper foil so that the thickness after curing was 50 μm or more, and this was heated and dried at 130° C. for 3 minutes until this was in a semi-cured state to obtain RCC.

(Metal-Clad Laminate)

A copper-clad laminate (CCL) (evaluation board) with a thickness of 100 μm in which copper foil was attached to both sides was obtained by bonding two pieces of RCC together and performing heating and pressing for 120 minutes under a vacuum condition at a temperature of 200° C. and a pressure of 5 to 10 kg/cm².

<Evaluation Test 1>

(Board Moldability)

The laminate (CCL) fabricated above was visually observed and evaluated as “good” when there was no swelling and adhesive properties were favorable and as “poor” when there was swelling or adhesive properties were poor.

(Glass Transition Temperature (Tg))

Tg was measured for a sample obtained by etching the entire surface of the outer layer copper foil of the copper-clad laminate (CCL) using a viscoelastic spectrometer “DMS100” manufactured by Seiko Instruments Inc. At this time, dynamic viscoelasticity measurement (DMA) was performed with a tensile module at a frequency of 10 Hz, and the temperature at which tan 6 was maximized when the temperature was raised from room temperature to 300° C. at a rate of temperature rise of 5° C./min was taken as Tg.

(Dielectric Properties: Relative Dielectric Constant (Dk) and Dielectric Loss Tangent (Df))

A laminate obtained by removing the copper foil from the copper-clad laminate (CCL) was used as a test piece, and the relative dielectric constant (Dk) and dielectric loss tangent (Df) of the test piece were measured by the cavity perturbation method. Specifically, the relative dielectric constant (Dk) and dielectric loss tangent (Df) of the test piece at 10 GHz were measured using a network analyzer (N5230A manufactured by Agilent Technologies, Inc.).

(Oven Heat Resistance)

Heat resistance was evaluated in conformity with the standard of JIS C 6481 (1996). The copper-clad laminate cut into a predetermined size was left in a thermostatic oven set to 240° C., 260° C., or 280° C. for 1 hour, and then taken out. Then, the test piece subjected to the heat treatment at each temperature was visually observed, and evaluated as “good” when blistering did not occur and as “poor” when blistering occurred.

The results are presented in Tables 1 and 2.

TABLE 1

| Material name | Example 1 | Example 2 | Example 3 | Example 4 | Example 5 | Example 6 | Example 7 | Example 8 | Example 9 |
|---|---|---|---|---|---|---|---|---|---|
| (Thermosetting | | | | | | | | | |
| resin) | | | | | | | | | |
| Modified | 75 | 75 | 75 | 75 | 75 | 75 | 75 | 75 | 75 |
| PPE-1 | | | | | | | | | |
| Modified | | | | | | | | | |
| PPE-2 | | | | | | | | | |
| DVB | 15 | 15 | 15 | 15 | 15 | 15 | 15 | 15 | 15 |
| TAIC | | | | | | | | | |
| B1000 | 10 | 10 | 10 | 10 | 10 | 10 | 10 | 10 | 10 |
| (Reaction | | | | | | | | | |
| initiator) | | | | | | | | | |
| Peroxide | | | | | | | | | |
| (Thermally | | | | | | | | | |
| expandable | | | | | | | | | |
| microcapsule) | | | | | | | | | |
| EM403 | 20 | | | | | | | | |
| EM504 | | 20 | | | | | | | |
| 980DU120 | | | 20 | | | | | | |
| F-230D | | | | 10 | 20 | 30 | | | |
| F-260D | | | | | | | 10 | 20 | 30 |
| (Others) | | | | | | | | | |
| Inorganic | | | | | | | | | |
| silica SO—C2 | | | | | | | | | |
| Neocellborn | | | | | | | | | |
| N#5000 | | | | | | | | | |
| Spangcell | | | | | | | | | |
| ST#44 | | | | | | | | | |

| Material name | Example 10 | Example 11 | Example 12 | Example 13 | Example 14 | Example 15 |
|---|---|---|---|---|---|---|
| (Thermosetting | | | | | | |
| resin) | | | | | | |
| Modified | | | | | | |
| PPE-1 | | | | | | |
| Modified | 70 | 70 | 70 | 70 | 70 | 70 |
| PPE-2 | | | | | | |
| DVB | | | | | | |
| TAIC | 30 | 30 | 30 | 30 | 30 | 30 |
| B1000 | | | | | | |
| (Reaction | | | | | | |
| initiator) | | | | | | |
| Peroxide | 2 | 2 | 2 | 2 | 2 | 2 |
| (Thermally | | | | | | |
| expandable | | | | | | |
| microcapsule) | | | | | | |
| EM403 | | | | | | |
| EM504 | | | | | | |
| 980DU120 | | | | | | |
| F-230D | 10 | 20 | 30 | | | |
| F-260D | | | | 10 | 20 | 30 |
| (Others) | | | | | | |
| Inorganic | | | | | | |
| silica SO—C2 | | | | | | |
| Neocellborn | | | | | | |
| N#5000 | | | | | | |
| Spangcell | | | | | | |
| ST#44 | | | | | | |

| | Example 2 | Example 3 | Example 4 | Example 5 | Example 6 | Example 7 | Example 8 | Example 9 |
|---|---|---|---|---|---|---|---|---|
| Item | Performance | Performance | Performance | Performance | Performance | Performance | Performance | Performance |
| Board | Good | Good | Good | Good | Good | Good | Good | Good |
| moldability | | | | | | | | |
| Tg (° C.) | 210° C. | 210° C. | 210° C. | 210° C. | 210° C. | 210° C. | 210° C. | 210° C. |
| Dielectric | 1.25 | 1.22 | 2.2 | 1.97 | 1.71 | 1.6 | 2.00 | 1.70 |
| constant | | | | | | | | |
| (@10 GHz) | | | | | | | | |
| Dielectric | 0.001 | 0.001 | 0.002 | 0.003 | 0.003 | 0.003 | 0.0035 | 0.0034 |
| loss tangent | | | | | | | | |
| (@10 GHz) | | | | | | | | |
| Oven heat | Good | Good | Good | Good | Good | Good | Good | Good |
| resistance 240° C. | | | | | | | | |
| Oven heat | Poor | Poor | Poor | Poor | Poor | Poor | Poor | Poor |
| resistance 260° C. | | | | | | | | |
| Oven heat | Poor | Poor | Poor | Poor | Poor | Poor | Poor | Poor |
| resistance 280° C. | | | | | | | | |

| | Example 10 | Example 11 | Example 12 | Example 13 | Example 14 | Example 15 | Example 16 |
|---|---|---|---|---|---|---|---|
| Item | Performance | Performance | Performance | Performance | Performance | Performance | Performance |
| Board | Good | Good | Good | Good | Good | Good | Good |
| moldability | | | | | | | |
| Tg (° C.) | 210° C. | 210° C. | 210° C. | 2!0° C. | 210° C. | 210° C. | 210° C. |
| Dielectric | 1.5 | 1.83 | 1.71 | 1.69 | 2.00 | 1.70 | 1.5 |
| constant | | | | | | | |
| (@10 GHz) | | | | | | | |
| Dielectric | 0.0039 | 0.003 | 0.003 | 0.003 | 0.0035 | 0.0034 | 0.0039 |
| loss tangent | | | | | | | |
| (@10 GHz) | | | | | | | |
| Oven heat | Good | Good | Good | Good | Good | Good | Good |
| resistance 240° C. | | | | | | | |
| Oven heat | Poor | Good | Good | Good | Good | Good | Good |
| resistance 260° C. | | | | | | | |
| Oven heat | Poor | Good | Good | Good | Good | Good | Good |
| resistance 280° C. | | | | | | | |

TABLE 2

| | Comparative | Comparative | Comparative | Comparative | Comparative |
|---|---|---|---|---|---|
| Material name | Example 1 | Example 2 | Example 3 | Example 4 | Example 5 |
| (Thermosetting resin) | | | | | |
| Modified PPE-1 | 75 | 75 | 75 | 75 | 75 |
| Modified PPE-2 | | | | | |
| DVB | 15 | 15 | 15 | 15 | 15 |
| TAIC | | | | | |
| B1000 | 10 | 10 | 10 | 10 | 10 |
| (Reaction initiator) | | | | | |
| Peroxide | | | | | |
| (Thermally expandable microcapsule) | | | | | |
| EM403 | | | | | |
| EM504 | | | | | |
| 980DU120 | | | | | |
| F-230D | | | | | |
| F-260D | | | | | |
| (Others) | | | | | |
| Inorganic silica SO-C2 | 10 | 20 | 30 | | |
| Neocellborn N#5000 | | | | 2 | |
| Spangcell ST#44 | | | | | 2 |

| | Comparative | Comparative | Comparative | Comparative | Comparative |
|---|---|---|---|---|---|
| | Example 1 | Example 2 | Example 3 | Example 4 | Example 4 |
| Item | Performance | Performance | Performance | Performance | Performance |
| Board moldability | Good | Good | Good | Poor | Poor |

| | | | | |
|---|---|---|---|---|
| Tg (° C.) | 210° C. | 210° C. | 210° C. | Unmeasurable as board |
| Dielectric constant (@10 GHz) | 2.3 | 2.3 | 2.4 | (Foamed too violently) |
| Dielectric loss tangent (@10 GHz) | 0.004 | 0.004 | 0.005 | |
| Oven heat resistance 240° C. | Good | Good | Good | |
| Oven heat resistance 260° C. | Good | Good | Good | |
| Oven heat resistance 280° C. | Good | Good | Good | |

As is apparent from the results presented in Tables 1 and 2, it was confirmed that a significantly low dielectric constant (2.2 or less) can be achieved by the present invention. It was further found that the dielectric loss tangent is also less than 0.004 and a cured product exhibiting low dielectric properties is obtained. Moreover, in Examples relating to the present invention, Tg is high, oven heat resistance is high, and moldability is excellent. It was also found that a resin composition can be obtained, which can afford a cured product having an excellent balance between heat resistance and low dielectric properties by selecting proper thermally expandable microcapsules depending on the maximum expansion temperature and the like. Particularly in Examples 10 to 15, significantly excellent oven heat resistance was exhibited.

On the other hand, in Comparative Examples 1 to 3, in which the thermally expandable microcapsules of the present invention were not used, it was not possible to obtain the sufficiently low dielectric properties intended by the present invention. In Comparative Examples 4 and 5, in which chemical blowing agents were used instead of thermally expandable microcapsules, violent foaming occurred even when a small amount of blowing agent was added, and it was not thus possible to fabricate a laminate (board) and measure the performance as a board.

<Evaluation Test 2>

For Examples 2, 5, 6, 9 and 12 and Comparative Examples 2 and 3, the density of the resin cured product was also evaluated by the method described below.

(Density)

An individual piece of 10 cm×10 cm was cut out from the cured resin plate (thickness: 300 in) with a press cutter. The weight of the individual piece measured using a precision balance was denoted as M (g). The volume V of individual resin piece was calculated by area S (10×10 cm²)×thickness H (0.03 cm). For calculation of the density, the density of individual piece of each resin cured product was calculated using the equation ρ=M/V.

The results are presented in Table 3.

TABLE 3

| | | | | | | Comparative | Comparative |
|---|---|---|---|---|---|---|---|
| Material name | Example 2 | Example 5 | Example 6 | Example 9 | Example 12 | Example 2 | Example 3 |
| (Thermosetting | | | | | | | |
| resin) | | | | | | | |
| Modified | | | | | 70 | | |
| PPE-2 | | | | | | | |
| Modified | 75 | 75 | 75 | 75 | | 75 | 75 |
| PPE-1 | | | | | | | |
| DVB | 15 | 15 | 15 | 15 | | 15 | 15 |
| TAIC | | | | | 30 | | |
| B1000 | 10 | 10 | 10 | 10 | | 10 | 10 |
| (Reaction | | | | | | | |
| initiator) | | | | | | | |
| Peroxide | | | | | 2 | | |
| (Thermally | | | | | | | |
| expandable | | | | | | | |
| microcapsule) | | | | | | | |
| EM504 | 20 | | | | | | |
| F-230D | | 20 | 30 | | 30 | | |
| F-260D | | | | 30 | | | |
| (Others) | | | | | | | |
| SO—C2 | | | | | | 20 | 30 |

| | | | | | | Comparative | Comparative |
|---|---|---|---|---|---|---|---|
| | Example 2 | Example 5 | Example 6 | Example 9 | Example 12 | Example 2 | Example 3 |
| Item | Performance | Performance | Performance | Performance | Performance | Performance | Performance |
| Density | 0.55 | 0.63 | 0.60 | 0.67 | 0.62 | 1.06 | 1.1 |
| (g/cm³) | | | | | | | |
| Board | Good | Good | Good | Good | Good | Good | Good |
| moldability | | | | | | | |
| Tg(° C.) | 210° C. | 210° C. | 210° C. | 210° C. | 210° C. | 210° C. | 210° C. |
| Relative | 1.22 | 1.71 | 1.6 | 1.5 | 1.69 | 2.3 | 2.4 |
| dielectric | | | | | | | |
| constant | | | | | | | |
| (@10 GHz) | | | | | | | |
| Dielectric | 0.001 | 0.003 | 0.003 | 0.0039 | 0.003 | 0.004 | 0.004 |
| loss tangent | | | | | | | |
| (@10 GHz) | | | | | | | |
| Oven heat | Good | Good | Good | Good | Good | Good | Good |
| resistance 240° C. | | | | | | | |
| Oven heat | Poor | Poor | Poor | Poor | Good | Good | Good |
| resistance 260° C. | | | | | | | |
| Oven heat | Poor | Poor | Poor | Poor | Good | Good | Good |
| resistance 280° C. | | | | | | | |

(Discussion)

As is apparent from the results presented in Table 3, it was confirmed that the cured product of the resin composition of the present invention exhibits low dielectric properties, heat resistance and the like, and can achieve weight saving as well.

On the other hand, in Comparative Examples 2 and 3, in which the thermally expandable microcapsules of the present invention were not used but an inorganic filler was added, weight saving as in Examples cannot be achieved.

This application is based on Japanese Patent Application Nos. 2020-94229 and 2020-94230 filed on May 29, 2020, the contents of which are incorporated herein.

In order to express the present invention, the present invention is adequately and sufficiently described above through embodiments with reference to specific examples, drawings and the like, but it should be recognized that those skilled in the art can easily modify and/or improve the above-described embodiments. Therefore, the modifications or improvements made by those skilled in the art are intended to be covered by the scope of the claims unless otherwise the modifications or improvements depart from the scope of the claims set forth in the claims.

### INDUSTRIAL APPLICABILITY

The present invention has wide industrial applicability in technical fields related to electronic materials and various devices using the electronic materials.

1. A resin composition for wiring board material comprising:
a thermosetting resin; and
a thermally expandable microcapsule,
wherein a relative dielectric constant (10 GHz) of a cured product of the resin composition is more than 1.0 and 2.2 or less.

2. The resin composition for wiring board material according to claim 1, wherein a density of a cured product of the resin composition is 0.3 to 1.0 g/cm³.

3. The resin composition for wiring board material according to claim 1, wherein the thermally expandable microcapsule is a hollow particle in which a liquid compound that is vaporized by heat is covered with a shell containing a thermoplastic polymer.

4. The resin composition for wiring board material according to claim 3, wherein the thermoplastic polymer is a polymer containing a structure derived from at least one selected from the group consisting of a nitrile-based monomer, a monomer having a carboxyl group, a (meth)acrylate ester-based monomer, a styrene-based monomer, and a monomer having an amide group.

5. The resin composition for wiring board material according to claim 4, wherein the thermoplastic polymer is a polymer containing a structure derived from at least one selected from the group consisting of a nitrile-based monomer, a monomer having a carboxyl group, and a (meth)acrylate ester-based monomer.

6. The resin composition for wiring board material according to claim 5, wherein the nitrile-based monomer contains at least one selected from acrylonitrile, methacrylonitrile, α-chloroacrylonitrile, α-ethoxyacrylonitrile, or fumaronitrile.

7. The resin composition for wiring board material according to claim 3, wherein the liquid compound contains at least one selected from the group consisting of a hydrocarbon-based compound, a hydrogen halide-based compound, an alcohol-based compound, an ether-based compound, and a ketone-based compound, and has a boiling point equal to or less than a softening temperature of the thermoplastic polymer.

8. The resin composition for wiring board material according to claim 3, wherein the shell does not dissolve in the liquid compound.

9. The resin composition for wiring board material according to claim 1, wherein a maximum thermal expansion temperature of the thermally expandable microcapsule is 100° C. to 280° C.

10. The resin composition for wiring board material according to claim 1, wherein an average thickness of the shell of the thermally expandable microcapsule is 1 to 8 μm.

11. The resin composition for wiring board material according to claim 1, wherein a volume of the thermally expandable microcapsule at maximum expansion at a maximum thermal expansion temperature is 3 times or more a volume of the thermally expandable microcapsule at room temperature (25° C.).

12. The resin composition for wiring board material according to claim 11, wherein the thermally expandable microcapsule is capable of maintaining an expansion volume at maximum expansion, the expansion volume being 3 times or more a volume at room temperature (25° C.), for 10 minutes or more.

13. The resin composition for wiring board material according to claim 1, wherein the thermally expandable microcapsule is contained at 1 to 50 parts by mass with respect to 100 parts by mass of a resin component including the thermosetting resin.

14. The resin composition for wiring board material according to claim 1, wherein the thermosetting resin contains at least one selected from the group consisting of a polyphenylene ether compound, a hydrocarbon-based resin, an epoxy resin, a maleimide compound, a phenolic resin, an oxetane resin, a benzoxazine compound, a liquid crystal polymer, and a compound having a polymerizable unsaturated group.

15. The resin composition for wiring board material according to claim 1, further comprising an inorganic filler at 1 to 300 parts by mass with respect to 100 parts by mass of a resin component including the thermosetting resin.

16. A prepreg for wiring board, comprising:
the resin composition according to claim 1 or a semi-cured product of the resin composition; and
a fibrous substrate.

17. A resin-coated film for wiring board, comprising:
a resin layer containing the resin composition according to claim 1 or a semi-cured product of the resin composition; and
a support film.

18. A resin-coated metal foil for wiring board, comprising:
a resin layer containing the resin composition according to claim 1 or a semi-cured product of the resin composition; and
a metal foil.

19. A metal-clad laminate for wiring board, comprising:
an insulating layer containing a cured product of the resin composition according to claim 1; and
a metal foil.

20. A wiring board comprising:
an insulating layer containing a cured product of the resin composition according to claim 1; and
wiring.

21. A metal-clad laminate for wiring board, comprising:
an insulating layer containing a cured product of the prepreg according to claim 16; and
a metal foil.

22. A wiring board comprising:
an insulating layer containing a cured product of the prepreg according to claim 16; and
wiring.
